(19) United States
(12) Patent Application Publication
(10) Pub. No.: US 2024/0208727 A1
(43) Pub. Date: Jun. 27, 2024

(54) TWO-MOTOR VERTICAL COMPONENT STORAGE SYSTEM

(71) Applicant: Accu-Assembly Incorporated, Andover, MA (US)

(72) Inventor: Yuen-Foo Michael Kou, Melrose, MA (US)

(21) Appl. No.: 18/533,568

(22) Filed: Dec. 8, 2023

Related U.S. Application Data
(60) Provisional application No. 63/477,327, filed on Dec. 27, 2022.

(51) Int. Cl. B65G 1/06

(52) U.S. Cl. CPC B65G 1/06; B65G 2203/0233; B65G 2203/041; G06V 20/50

(57) ABSTRACT

A component storage system includes a storage stack with vertical stack supports, an operator access station, and an automated elevator. The automated elevator stores trays in the storage stack by lifting a tray from the access station and moving the lifted tray into the designated tray storage location. The automated elevator includes a tray carrier, two elevator motors, and two support sensors. Each support sensor is responsive to vertically-spaced features of a respective one of the vertical stack supports. The two elevator motors are each independently operable to raise the tray carrier to at least approximate alignment with the designated tray storage location and, as a function of feedback from the support sensors, to adjust a tilt of the tray carrier to level the lifted tray with respect to the storage stack. The trays have repositionable dividers.

### CROSS-REFERENCE TO RELATED APPLICATION

This application claims the benefit under 35 U.S.C. § 119(e) of U.S. Patent Application No. 63/477,327, entitled “Two-Motor Vertical Component Storage System,” filed Dec. 27, 2022, which is incorporated herein by reference in its entirety.

### FIELD OF THE DISCLOSURE

This disclosure relates to storage and inventory management systems.

### BACKGROUND OF THE DISCLOSURE

Storing and managing the inventory of small items such as electronic component reels, mechanical parts, or pharmaceutical products can be costly and time-consuming. Storing and retrieving small items in large stacks or piles can present many challenges. In some cases, finding and storing specific items within a large group of items can be especially difficult. Some challenges include finding ways to quickly store and retrieve items using automated equipment. Methods and equipment for improving storage systems are sought.

### SUMMARY

Implementations of the present disclosure include a component storage system includes a storage stack, an operator access station, and an automated elevator. The storage stack defines discrete tray storage locations spaced vertically along the stack between vertical stack supports. The operator access station has a surface adapted to support a movable tray. The automated elevator stores trays in the storage stack by lifting a tray from the access station surface to an elevation of a designated one of the discrete tray storage locations of the storage stack, and then moving the lifted tray into the designated tray storage location between the vertical stack supports. The automated elevator includes a tray carrier, two elevator motors, and two support sensors. The tray carrier has a carrier motor operable to move the tray from the tray carrier into the designated tray storage location once the tray carrier is vertically aligned with the designated tray storage location. The two elevator motors are operable to lift the tray carrier. The elevator motors are spaced apart such that each elevator motor is closer to a respective one of the vertical stack supports. The two support sensors are attached to the tray carrier. Each support sensor is positioned to be responsive to vertically-spaced features of a respective one of the vertical stack supports. The two elevator motors are each independently operable to raise the tray carrier to at least approximate alignment with the designated tray storage location and, as a function of feedback from the support sensors, to adjust a tilt of the tray carrier to level the lifted tray with respect to the storage stack.

In some implementations, the component storage system also includes a controller electrically coupled to and configured to receive information from the two support sensors. The controller controls, based on the information received from the two support sensors, the two elevator motors to adjust the tilt of the tray carrier to level the lifted tray with respect to the vertically-spaced features, aligning the tray carrier with the designated tray storage location.

In some implementations, the controller controls the two elevator motors to first raise the tray carrier to a first elevation before the support sensors detect the vertically-spaced features, then to a second elevation in which the support sensors initially detect a point of the vertically-spaced features, and then to a third elevation in which the support sensors are spaced a predetermined vertical distance from the vertically spaced features and the tray carrier is aligned with the designated tray storage location.

In some implementations, the automated elevator retrieves a selected tray from the storage stack by extracting the selected tray from its respective tray storage location and moving the selected tray to the operator access station. Extracting the selected tray includes moving the tray carrier to at least approximate alignment with the tray storage location, adjusting, as a function of feedback from the support sensors, the tilt of the tray carrier to level the tray carrier with respect to the respective tray storage location, and then pulling the selected tray unto a support surface of the tray carrier.

In some implementations, the automated elevator further includes two belts each engaged with and driven by a respective one of the two elevator motors. Each of the two belts is attached to a respective end of the tray carrier to selectively raise each of the ends independently from each other to adjust the tilt of the tray carrier to level the lifted tray with respect to the storage stack.

In some implementations, the vertically-spaced features include multiple pairs of visual features. Each pair is associated with one of the discrete tray storage locations and is detectable by the two support sensors. The two elevator motors raise the tray carrier to a predetermined elevation along the storage stack, and then move, as a function of feedback from the support sensors detecting the pair of visual features, the tray carrier to a final position with respect to the respective pair of visual features. In some implementations, each of the two elevator motors is coupled to an encoder. The elevator motors are operable to raise the tray carrier based on feedback from the encoder both to raise the tray carrier to at least approximate alignment with the designated tray storage location, and to adjust the tilt of the tray carrier. In some implementations, the vertical stack supports include two columns of a frame of a vertical storage rack. Each of the two columns defines holes and each pair of visual features includes a pair of holes. Each hole of the pair of holes resides on one side of a respective discrete tray storage location and resides at the same elevation.

In some implementations, the tray carrier also has a second carrier motor and two tab sensors. The two carrier motors move multiple tabs that engage a respective side of the tray to load the tray on the tray carrier or offload the tray from the tray carrier. The two tab sensors are attached to the tray carrier and are positioned to be responsive to the presence of a respective one of the tabs. The component storage system determines, based on feedback from the tab sensors, whether a tray is on or off the tray carrier.

In some implementations, the tray carrier has two chains each driven by one of the carrier motors. The tabs include two tabs attached to one of the chains to engage one side of the tray and two tabs attached to the other one of the chains to engage an opposite side of the tray. The carrier motors are each independently operable, as a function of feedback from the tab sensors, to align the tabs of the first chain with the tabs of the second chain to allow the tabs to engage and move the tray from a tray storage location to the tray carrier in between the two chains.

In some implementations, the access station includes a camera positioned such that a tray supported on the surface is within a field of view of the camera. The field of view spans multiple discrete component storage locations of the tray. The camera generates data representing an image of the tray, from which the system (a) identifies a component on the tray, and (b) determines where on the tray the component is located. The component storage system includes a machine learning image processing system configured to process the data from the camera and identify, based on a machine learning algorithm, each component on the tray based on a shape or other physical characteristic of the component.

Implementations of the present disclosure also include a storage system that includes a storage stack, and an elevator. The storage stack defines discrete tray storage locations residing between vertical stack supports. The elevator stores trays in the storage stack by moving a tray from an access station of the storage stack to an elevation of a designated one of the discrete tray storage locations of the storage stack, and then moving the lifted tray into the designated tray storage location. The elevator includes a tray carrier and two elevator motors. The tray carrier has a carrier motor that moves the tray from the tray carrier into the designated tray storage location. The two elevator motors lift the tray carrier. The elevator motors are spaced apart such that each elevator motor moves a side of the tray carrier that is closer to a respective one of the vertical stack supports. The two elevator motors are each independently operable to first raise the tray carrier to a first elevation, and then, as a function of feedback from support sensors positioned to be responsive to vertically-spaced features of a respective one of the vertical stack supports, to a second elevation in which the tray carrier is leveled with respect to the designated tray storage location.

In some implementations, the storage system also has a controller that receives information from the two support sensors. The controller controls, based on the information received from the two support sensors, the two elevator motors to adjust the tilt of the tray carrier to level the lifted tray with respect to the vertically-spaced features, aligning the tray carrier with the designated tray storage location.

In some implementations, the controller controls the two elevator motors to first raise the tray carrier to a first elevation in which the support sensors initially detect a point of the vertically-spaced features, and then to a second elevation in which the support sensors are spaced a predetermined vertical distance from the vertically spaced features and the tray carrier is aligned with the designated tray storage location.

In some implementations, the access station includes a camera positioned such that a tray supported on the surface is within a field of view of the camera. The field of view spans multiple discrete component storage locations of the tray. The camera generates data representing an image of the tray, from which the system (a) identifies a component on the tray, and (b) determines where on the tray the component is located. The component storage system includes a machine learning image processing system that processes the data from the camera and identifies, based on a machine learning algorithm, each component on the tray based on a shape or other physical characteristic of the component.

Implementations of the present disclosure include a system that includes at least one processing device and a memory communicatively coupled to the at least one processing device. The memory stores instructions which, when executed, cause the at least one processing device to perform operations. The operations include receiving data from an input device of a component storage assembly, the component storage assembly including a storage stack defining discrete tray storage locations residing between vertical stack supports and an elevator configured to store trays in the storage stack elevator, the elevator including a tray carrier with a carrier motor, two elevator motors operable to lift the tray carrier, a controller configured to control the two elevator motors, and support sensors attached to the tray carrier, each support sensor positioned to be responsive to vertically-spaced features of a respective one of the vertical stack supports. The operations also include determining, based on the data from the input device, a location of a designated one of the discrete tray storage locations of the storage stack in which a tray is to be stored. The operations also include transmitting, based on the determined location, first instructions to the controller to control the two elevator motors to raise the tray carrier to at least approximate alignment with the designated tray storage location. The operations also include receiving, from the support sensors, feedback representing a presence of respective features of the vertically-spaced features. The operations also include transmitting, based on the sensor feedback, second instructions to the controller to control the two elevator motors to adjust a tilt of the tray carrier to level the lifted tray with respect to the respective features. The operations also include transmitting third instructions to the controller to control the carrier motor to move the tray from the tray carrier into the designated tray storage location.

Implementations of the present disclosure also include a method that includes receiving, by a system including one or more computers in one or more locations, data from an input device of a component storage assembly. The component storage assembly includes a storage stack including an operator access station and defining discrete tray storage locations residing between vertical stack supports. The component storage assembly also includes an elevator that stores trays from the operator access station in the storage stack elevator. The elevator includes a tray carrier with a carrier motor, two elevator motors operable to lift the tray carrier, a controller that controls the two elevator motors, and support sensors attached to the tray carrier. Each support sensor is positioned to be responsive to vertically-spaced features of a respective one of the vertical stack supports. The method also includes determining, by the system and based on the data from the input device, a location of a designated one of the discrete tray storage locations of the storage stack in which a tray is to be stored. The method also includes transmitting, by the system and based on the determined location, first instructions to the controller to control the two elevator motors to raise the tray carrier to at least approximate alignment with the designated tray storage location. The method also includes receiving, by the system and from the support sensors, feedback representing a presence of respective features of the vertically-spaced features. The method also includes transmitting, by the system and based on the sensor feedback, second instructions to the controller to control the two elevator motors to adjust a tilt of the tray carrier to level the lifted tray with respect to the respective features. The method also includes transmitting, by the system, third instructions to the controller to control the carrier motor to move the tray from the tray carrier into the designated tray storage location.

In some implementations, the method also includes, before transmitting the first instructions, transmitting, by the system, fourth instructions to the controller to control the two elevator motors to move the tray carrier to at least approximate alignment with a support surface of the operator access station. The method also includes transmitting, by the system, fifth instructions to the controller to control the two elevator motors to adjust a tilt of the tray carrier to level the tray carrier with respect to the support surface of the operator access station. The method also includes transmitting, by the system, sixth instructions to the controller to control the carrier motor to load the tray from the operator access station unto the tray carrier.

In some implementations, the method also includes receiving, by the system and from the input device, information including an identifier of an item to be retrieved from the storage stack. The method also includes, determining, by the system and based on the information from the input device, a location of one of the discrete tray storage locations in which a tray containing the item is stored.

The method also includes transmitting, by the system and based on the determined location, fourth instructions to the controller to control the two elevator motors to raise the tray carrier to at least approximate alignment with the designated tray storage location. The method also includes receiving, by the system and from the support sensors, feedback representing a presence of respective features of the vertically-spaced features. The method also includes transmitting, by the system and based on the sensor feedback, fifth instructions to the controller to control the two elevator motors to adjust a tilt of the tray carrier to level the lifted tray carrier with respect to the respective features and the tray storage location. The method also includes transmitting, by the system, sixth instructions to the controller to control the carrier motor to move the tray from the tray storage location to the tray carrier. The method also includes transmitting, by the system, seventh instructions to the controller to control the elevator motors to move the tray carrier to at least approximate alignment with a support surface of the operator access station. The method also includes transmitting, by the system, eighth instructions to the controller to control the two elevator motors to adjust a tilt of the tray carrier to level the tray carrier with respect to the support surface of the operator access station. The method also includes transmitting, by the system, ninth instructions to the controller to control the carrier motor to move the tray from the tray carrier to the support surface of the operator access station.

In some implementations, the method also includes receiving, by the system and from two encoders each attached to one of the elevator motors, encoder feedback. Transmitting the first and second instructions includes transmitting, based on the encoder feedback, the first instructions to control the two elevator motors to raise the tray carrier a predetermined distance with respect to a base of the storage stack, and then transmitting, based on the encoder feedback, the second instructions to control the two elevator motors to raise the tray carrier a predetermined distance with respect to the vertically-spaced features.

Another aspect of the invention features a configurable component storage tray, which may or may not be configured for use in the system discussed above. The storage tray features a tray body having a bottom surface and four side walls defining a recess therebetween, and at least one L-shaped tray divider having two arms extending to respective arm ends and divider selectively positionable in two different positions within the recess. One position is a deployed position in which the arm ends are secured to two adjacent side walls of the tray body with the two arms otherwise spaced from the side walls to define a tray receptacle of an area smaller than the recess. Another position is a stowed position in which the two arms lie along the two adjacent side walls, such that the divider is stowed in a corner of the tray body.

In some examples, the tray body also has a corner wall extending from the bottom surface into the recess adjacent the two adjacent side walls to define a space sized to accommodate the tray divider in its stowed position, with the tray divider positioned between the corner wall and the two adjacent side walls.

In some embodiments, the bottom surface of the tray body defines a respective notch adjacent each of the two adjacent side walls, the notch configured to releasably mate with a locking feature at one of the arm ends of the tray divider, to releasably secure the arm ends to the tray body at the two adjacent side walls. In some cases, each arm end of the tray divider has a projection, such as a pawl, sized to fit into a respective one of the notches. Preferably, each notch has a release portion contiguous with a latch portion, the release portion sized to accept the projection of an arm end as the tray divider is placed against the bottom surface, the latch portion being sized to prevent release of the projection with the projection moved along the side wall from the release portion into the latch portion. The side wall may have a detent, such as a rib, aligned with the notch to resist arm end motion to move the projection between the release and latch portions of the notch. In some cases, the tray divider defines a groove positioned to accommodate the rib when the tray divider is in its stowed position.

In some examples there are two tray dividers. In other words, the L-shaped tray divider mentioned above is a first tray divider, the tray receptacle is a first tray receptacle and the corner is a first corner, and the storage tray also includes a second tray divider having two arms extending to respective arm ends. T second tray divider is selectively positionable in two different positions within the recess, including a deployed position in which the arm ends are secured to two adjacent side walls of the tray body with the two arms otherwise spaced from the side walls to define a second tray receptacle of an area smaller than the recess, and a stowed position in which the two arms lie along the two adjacent side walls, such that the divider is stowed in a second corner of the tray body opposite the first corner.

In some cases, each of the first and second tray dividers has a hub from which the arms extend to define an angle therebetween, and wherein, with the first and second tray dividers in their deployed positions, the hubs of the first and second tray dividers are adjacent one another. The bottom surface of the tray body may be configured to accept a releasable fastener to hold the hubs against the bottom surface of the tray body.

In some embodiments, the recess is square and, with the first and second tray dividers in their deployed positions, the hubs of the first and second tray dividers are disposed at a center of the square recess, thereby dividing the recess into four similarly sized areas.

Preferably, the side walls are all of height, as measured from the bottom surface, less than ten percent of a maximum lateral extent across the bottom surface, or of a maximum length of any of the side walls.

Particular implementations of the subject matter described in this specification can be implemented so as to realize one or more of the following advantages. For example, the vertical component storage system of the present disclosure allows the system to align the tray carrier automatically and in real time, compensating for imperfect mechanical assembly and alignment. Furthermore, the vertical component storage system can use small motors because the load is distributed between two motors, which can increase the volume dedicated to storage and can help save assembly time and resources. Additionally, the vertical component storage system can precisely move each end of the tray independently from each other, which is useful in a system where the storage slots are only millimeters apart from each other.

### BRIEF DESCRIPTION OF THE DRAWINGS

FIG. 1 is a perspective, schematic view of a vertical storage system according to implementations of the present disclosure.

FIGS. 2-5 are side, schematic views of sequential steps of storing a tray in the vertical component storage system in FIG. 1.

FIGS. 6-7 are side, schematic views of sequential steps of retrieving a tray from the vertical storage system in FIG. 1.

FIG. 8 is a top perspective view of an elevator system.

FIG. 9 is a top view of the elevator system in FIG. 8.

FIG. 10 is a top perspective view of a section of the elevator system in FIG. 8.

FIG. 11 is a bottom perspective view of the elevator system in FIG. 8.

FIG. 12 is a top perspective view of an elevator motor.

FIGS. 13-16 are top perspective views of sequential steps of aligning an extractor with a slot of the vertical storage system to store or retrieve a tray.

FIGS. 17-20 are top perspective views of sequential steps of aligning an extractor with a slot of the vertical storage system to store or retrieve a tray.

FIG. 21 is a top schematic, perspective view of a tray according to a first implementation of the present disclosure.

FIG. 22 is a top schematic, perspective view of a tray according to a second implementation of the present disclosure.

FIG. 23 is a schematic illustration of an example control system or controller of the vertical storage system.

FIG. 24 is a flow chart of a method of moving a tray carrier.

FIG. 25 is a flow chart of a method of storing a tray.

FIG. 26 is a perspective view of a tray body.

FIG. 27 is a perspective view of a configurable component storage tray, with the tray body of FIG. 26 and two deployable tray dividers.

FIG. 28 shows the storage tray of FIG. 26, with one of the two tray dividers in a stowed position.

FIG. 29 is a perspective view of a tray divider.

FIG. 30 is an enlarged view of an end of one of the arms of the tray divider.

FIG. 31 is an enlarged view of a notch in the bottom surface of the tray body, for receiving the projection of the arm end.

Similar reference numbers denote similar components.

### DETAILED DESCRIPTION OF THE DISCLOSURE

The vertical storage system of the present disclosure includes a vertical storage rack with multiple bays that store carriers (e.g., trays or pallets) that contain one or more small items (e.g., electronic component reels). The vertical storage rack has an operator access station where an operator can access the trays to retrieve or store trays. The vertical component storage system includes an elevator with a car or tray carrier that moves the trays between the operator access station and storage bays of the vertical storage rack to store or retrieve trays. The elevator has two motors that move the ends of the tray carrier independently from each other to quickly tilt and align the tray carrier with the bays to store or retrieve trays.

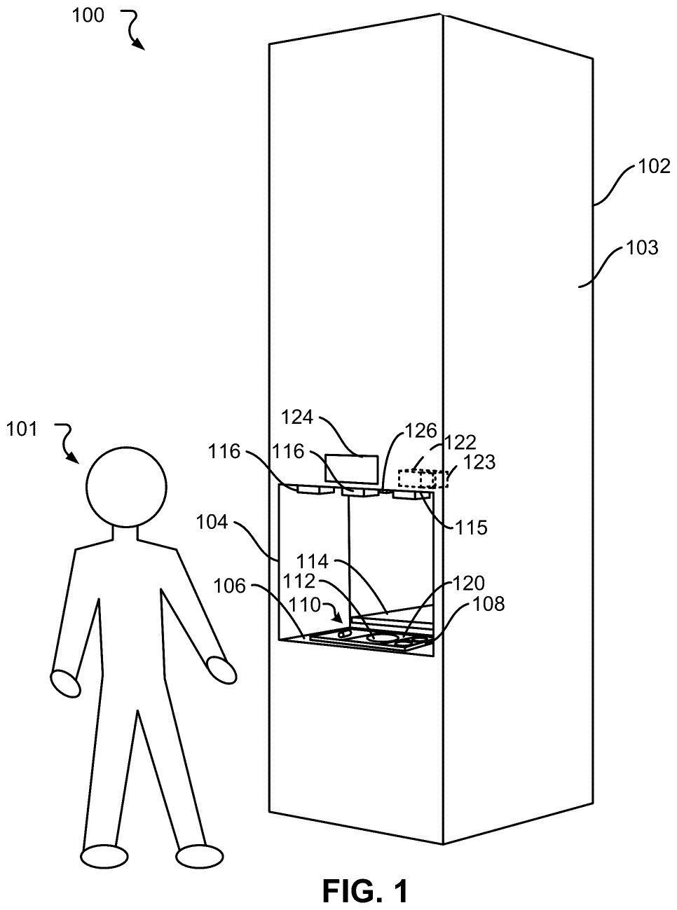

FIG. 1 depicts a vertical component storage system 100 that includes a storage stack 102 (e.g., a vertical storage rack) to store multiple items or components 110. The components 110 can be tape reels used in surface mount technology (SMT) systems. Tape reels are used in the production of electronic circuits, in which electronic components from tape reels are placed directly onto the surface of printed circuit boards. SMT board population requires many different components, and the specific list of components will change with each board design being produced. This requires manufacturers to maintain and manage inventories of hundreds, if not thousands, of different reels. Furthermore, partial reels often must be returned to inventory when switching from one run to the next. Managing the large tape reel inventory can be challenging. The vertical component storage system 100 leverages cameras or image sensors, data querying, elevator sensors, and vertical lift technology to provide an effective storage system.

The vertical component storage system 100 is not limited to storing tape reels. For example, the vertical component storage system 100 can be used to store narrow or small items such as small electronic components, printed circuits, hand tools, small auto parts, medications, etc. For example, the vertical component storage system 100 can be used in the healthcare industry such as in pharmacies to store prescription medications or in hospitals to store instruments, surgical kits, diagnostic tools, medical supplies, and patient records. Moreover, the vertical component storage system 100 can store dissimilar items and a combination of different products within the same system.

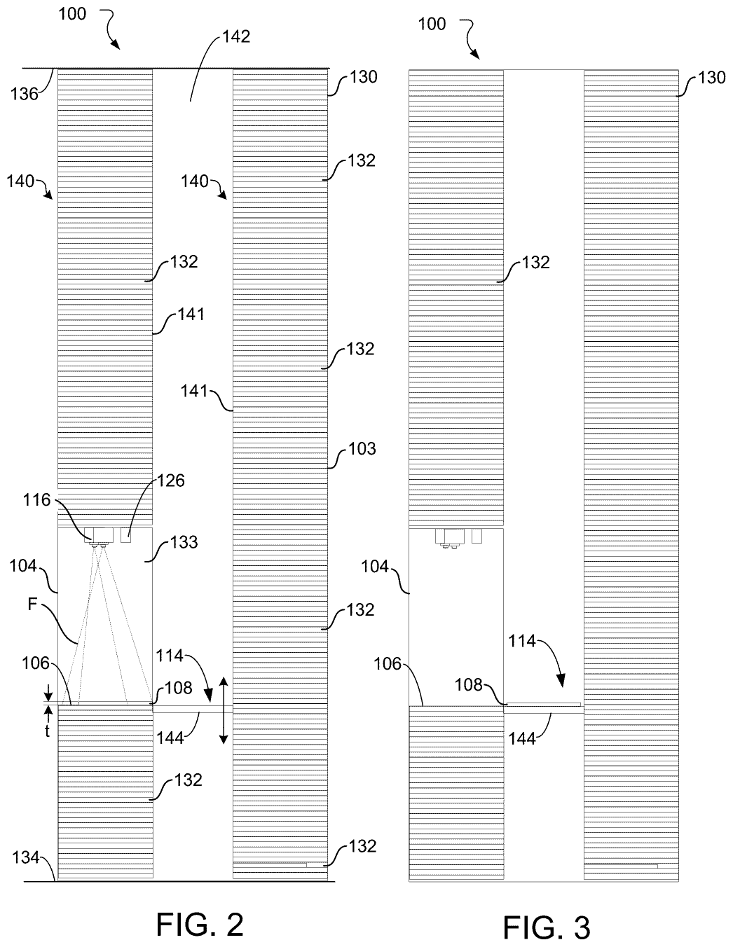

An operator 101 can use the vertical component storage system 100 to store and retrieve components to and from the system 100. The storage stack 102 can be an open rack system that has discrete tray storage locations (see FIGS. 2-7) at different levels or heights of the storage stack 102. The open rack system is such that each tray storage location is exposed to an exterior environment on which the operator resides. In some cases, the storage stack 102 can be enclosed, with a housing 103 that defines volume containing the stack 102. Each discrete tray storage location can store one or more trays.

The vertical component storage system 100 also includes an operator access station or loading station 104 that has a surface 106 that supports a movable tray or pallet 108. The tray 108 contains one or more components 110 such as electronic component reels 112. The vertical component storage system 100 also has an automated elevator 114 that moves the tray 108 from the surface 106 of the operator access station 104 to a designated one of the discrete tray storage locations of the storage stack 102. The automated elevator 114 also retrieves selected trays from the storage stack 102 and brings the trays 108 to the operator access station 104, where the operator 101 can retrieve the tray 108 or a component 112 of the tray 108. When the component 112 has been retrieved, the operator 101 can press a button or otherwise input instructions to indicate that the operation is finished so the elevator 114 can take the tray 108 back to its storage location.

The operator access station 104 has one or more cameras 116 attached or fixed to a ceiling 115 (or to the walls) of the operator access station 104. Additionally, the cameras 116 can be fitted on a motion system to move the field of view of the cameras. The cameras 116 are positioned such that the tray 108 supported on the surface 106 is within a field of view of the cameras 116. The field of view spans multiple discrete component storage locations 120 of the tray 108. Each location 120 can be arranged to receive one component 110.

The vertical component storage system 100 includes one or more computers or processing devices 122 (e.g., a system including one or more computers) communicatively coupled to the cameras 116. The processing device 122 can reside over the operator access station 104 (as shown in FIG. 1) or can reside at a different location such as at a bottom end of the storage stack 102 or outside of the storage stack 102. The cameras 116 generate data that represents an image of the tray 108. The processing device 122 can, based on data received from the camera, (a) identify a component 110 on the tray 108, and (b) determine where on the tray 108 (e.g., in which component storage location 120 of the tray 108) the component 112 is located. The processing device 122 also determined where in the vertical stack the component 110 should be stored.

The processing device 122 can also output information to communicate the identified discrete component storage location 120 to the operator 101 at the operator access station 104. For example, the processing device can be communicatively coupled to an electronic user interface 124 to transmit the location information for the user interface electronic display 124 to display the information. Additionally, the processing device 122 can be communicatively coupled to one or more illumination sources 126 (e.g., a laser or an LED light) that radiates, based on instructions from the processing device 122, light unto the component that is to be retrieved from the tray.

The system 100 can also use artificial intelligence such as machine-learning algorithms to identify the components 110. For example, the processing device 122 can use an image processing system that includes a machine-learning process (e.g., a deep learning process implemented, for example, using a similarity metric or a classifier such as support vector machine or a neural network) to identify the component 110 and/or a category of the component 110. Thus, the processing device 122 can use machine-learning processes to fine tune the identification process of the components 110 and thus be able to quickly identify components of different shapes, types, and dimensions. This can be particularly useful in the pharmaceutical industry where many types of prescription medications and medicines need to be stored in high-density storage systems. Using machine learning to identify the components can be useful in any industry in which small objects of several different shapes and categories are to be stored.

The processing device 122 is communicatively coupled to (or includes) one or more controllers 123. The controller 123 is operably coupled to the automated elevator 114 to control, based on information received from the processor 122, the vertical and horizontal movement of the elevator 114 (e.g., the up and down movement and the loading and unloading movement). Additionally, the controller 123 can control other components of the system 100, such as the cameras 116 and the illumination source 126.

The controller 123 can be coupled to multiple components of the automated elevator 114. The controller 123 can reside above the operator access station 104. In some implementations, the controller 123 can reside at the automated elevator 114 or a different location of the vertical component storage system 100. In some implementations, the controller 123 can be implemented as a distributed computer system disposed partly at the vertical component storage system 100 and partly outside the vertical component storage system 100. The computer system can include one or more processors and a computer-readable medium storing instructions executable by the one or more processors to perform the operations described here. In some implementations, the controller 123 can be implemented as processing circuitry, firmware, software, or combinations of them.

Referring now to FIG. 2, the vertical component storage system 100 has a frame 130 (e.g., the frame of the storage stack 102) that defines tray storage locations 132 (e.g., multiple stacked bays or slots) each arranged to receive and store one or more trays 108. The frame 130 can be supported on a floor 134 of a building or room in which the vertical component storage system 100 resides, and can extend to or near a ceiling 136 of the building or room. The frame 130 of the vertical component storage system 100 can have a height of, for example, between 2 and 8 meters. Additionally, the frame 130 of the vertical component storage system 100 can have a footprint of, for example, between 1.5 and 3 (e.g., 2.2) square meters or more. Thus, the vertical component storage system 100 can have a small footprint while providing high-density storage. The storage stack 102 can store, for example, between 2000 and 10000 items.

The cameras 116 are positioned such that the tray 108 supported on the surface 106 of the operator access station 104 is within a field of view “F” of the camera 116. The field of view “F” spans multiple discrete component storage locations of the tray 108. For example, the field of view “F” of the cameras 116 can span the entire tray 108 or part of the tray 108. In some implementations, the field of view “F” of the camera 116 can span the entire support surface 106 of the operator access station 104.

The vertical component storage system 100 can have two columns 140 of bays 132. The columns 140 can be separated by an elevator volume or enclosure 142 where the automated elevator 114 resides. Each bay 132 can be a slot defined between two rails that receive and support a tray. In some cases, the each bay 132 has a floor or support surface and a ceiling, with a volume defined between the floor and ceiling. Each bay 132 has an open end facing the elevator enclosure 142 to receive a tray from the automated elevator 114. Each bay 132 can have has side and back walls defined by the housing 103 of the vertical component storage system 100.

Each bay 132 can have a height that is slightly larger than a thickness “t” of the trays 108. For example, if the tray 108 has a thickness “t” of about 16 millimeters, each bay 132 can have a height (e.g., a pitch) of, for example, between 20 to 30 (e.g., 27) millimeters or more. The operator access station 104 can be arranged as a bay 133 of the stacked bays 132. For example, the bay 133 has a height larger than a height of the rest of bays 132, but can have a width that is equal or similar to the width of the stacked storage bays 132.

The automated elevator 114 includes a tray carrier 144 (e.g., an extractor) that includes a car or platform that moves vertically along the elevator enclosure 142 of the vertical component storage system 100 to store and retrieve trays 108. For example, the tray carrier 144 moves up and down along the height of the component storage system 100 to move trays 108 between the operator access station 104 and a selected storage bay 132.

Once the operator places a tray 108 on the support surface 106, the vertical component storage system 100 can automatically detect at least one of: i) which tray storage location of the tray 108 is empty and which one has a component, ii) which component is in which tray storage location, and iii) an identifier (e.g., an ID number) of the tray 108. Once the vertical component storage system 100 identifies the components in the tray 108, the vertical component storage system 100 determines in which bay 132 the tray 108 will be stored. For example, each bay 132 can be associated with a tray identifier so that the vertical component storage system 100 stores each tray 108 in its designated bay 132.

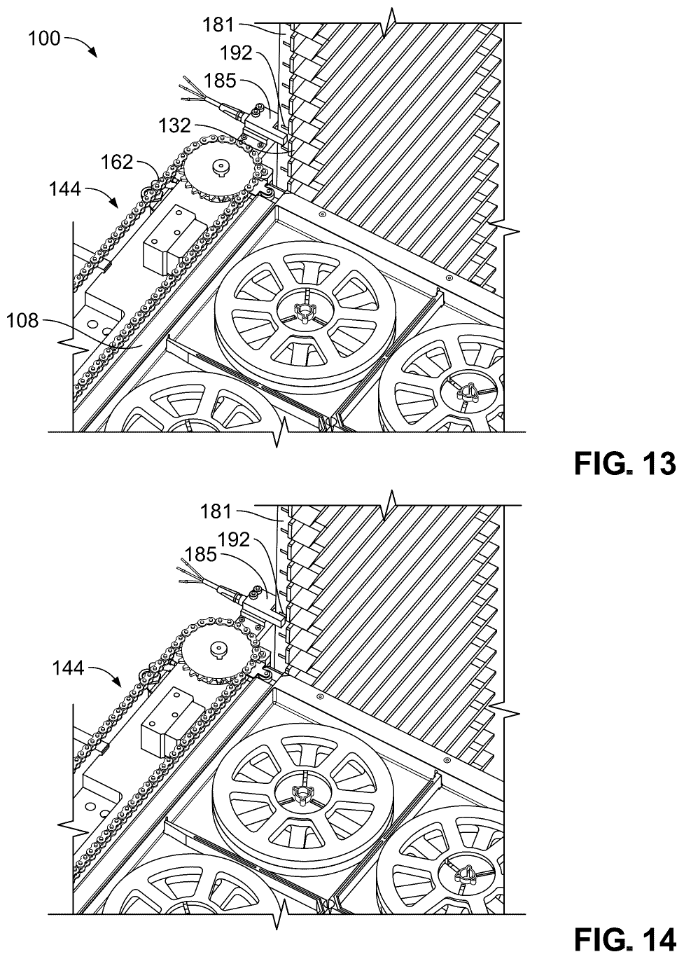

Referring to FIGS. 2 and 3, once the vertical component storage system 100 associates the components to the tray 108 and the tray to its designated bay 132, the tray carrier 144 moves the tray 108 from the support surface 106 to a top surface of the tray carrier 144. Then, the automated elevator 114 moves the tray carrier 144 up or down to the selected or designated bay. As further described in detail below with respect to FIGS. 13-16, the tray carrier 144 is leveled with respect to the support surface 106 before engaging the tray 108 to move the tray 108 to the top surface of the tray carrier 144.

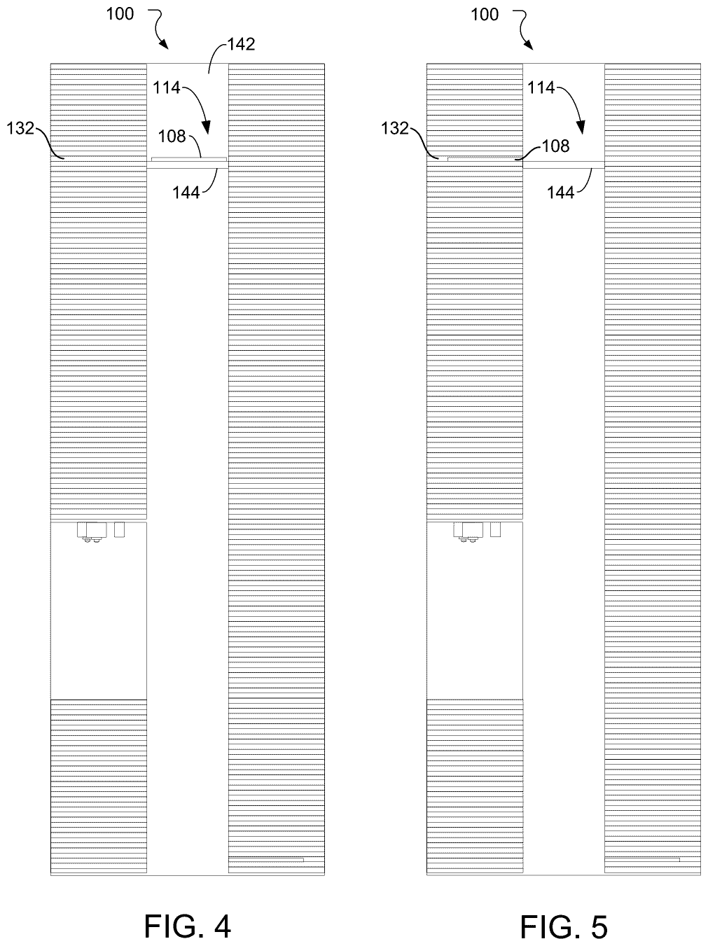

Referring now to FIGS. 4 and 5, with the tray 108 loaded on the tray carrier 144, the automated elevator 114 moves the tray carrier 144 vertically along the elevator enclosure 142 to the designated storage bay 132 where the tray 108 is to be stored. As shown in FIG. 5, once the tray 108 is aligned with the open end of the designated bay 132, the tray carrier 144 moves the tray 108 from the top surface of the tray carrier 144 to the interior volume of the bay 132.

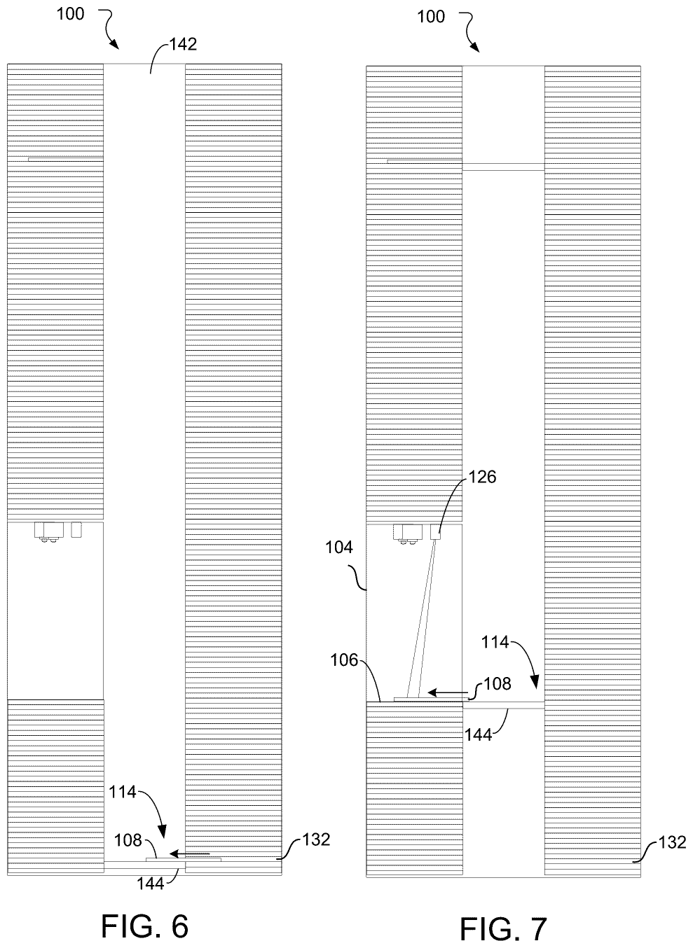

As shown in FIGS. 6 and 7, to retrieve a component, the operator can input (e.g., by using the electronic user interface 124 shown in FIG. 1) into the vertical component storage system 100 information indicating which component is to be retrieved. Based on the input information, the vertical component storage system 100 determines in which bay 132 is the tray 108 that contains the component to be retrieved. With the tray carrier 144 empty, the automated elevator 114 moves the tray carrier 144 vertically along the elevator enclosure 142 to the storage bay 132. Once the carrier 144 is near the bay 132, the elevator 114 aligns the tray carrier 144 with the bay 132. Once the tray carrier 144 is leveled with the bay 132, the tray carrier 144 engages an end of the tray 108 to move the tray 108 from the bay 132 to the top surface of the tray carrier 144.

As shown in FIG. 7, with the tray 108 loaded on the tray carrier 144, the automated elevator 114 moves the tray carrier 144 vertically along the elevator enclosure 142 to the operator access station 104, where the tray carrier 144 moves the tray 108 from the top surface of the tray carrier 144 to the support surface 106. As depicted in FIG. 7, the illumination source 126 of the vertical component storage system 100 can radiate light to the component or components that are to be retrieved from the tray 108.

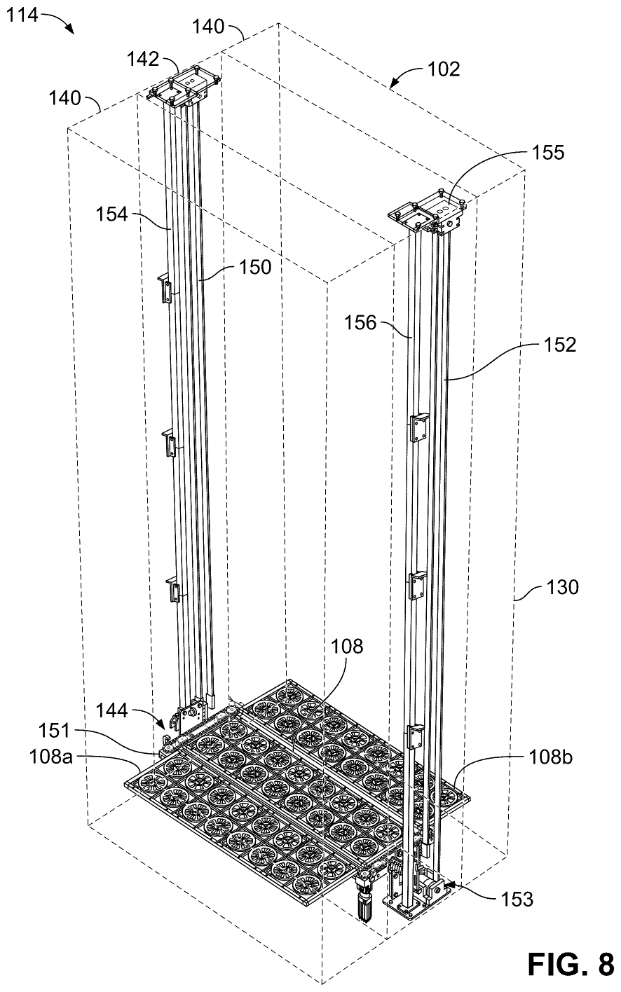

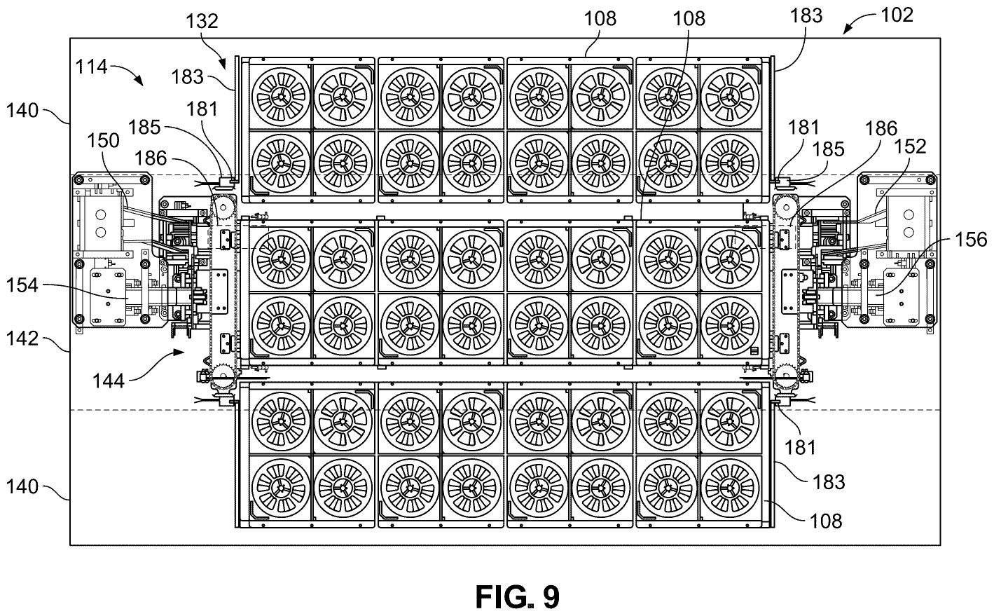

FIGS. 8 and 9 show the automated elevator 114 of the storage stack 102. The automated elevator 114 resides within the elevator volume 142. The elevator volume 142 is disposed between the two columns 140 of bays. The elevator 114 is shown carrying a tray 108 next to two stored trays 108a, 108b. The first tray 108a is stored in the first (e.g., front) column 140 of bays and the second tray 108b is stored in the second (e.g., rear) column 140 of trays.

As shown in FIG. 9, each column 140 of bays has two vertical stack supports 181 (e.g., frame columns) on each side of the bays 132. In other words, the bays 132 are defined between two vertical supports 181. The vertical supports 181 can be attached to or be part of a frame sidewall 183 that defines the walls of the bays 132. For example, the vertical stack supports 181 can be two columns of a frame of a vertical storage rack. As further described in detail below, the supports 181 can be made of punched sheet metal with holes or slots associated with each bay 132.

The automated elevator 114 stores trays 108 in the storage stack 102 by first lifting a tray 108 from the access station to an elevation of a designated one of the bays 132, and then moving the lifted tray 108 into the designated bay 132 between the vertical supports 181.

Still referring to FIG. 9, the tray carrier 144 has four support sensors 185 (e.g., homing sensors, proximity sensors, motion detectors, or image sensors). The support sensors 185 can determine a ‘local home’ for each slot to eliminate mechanical variation or misalignment. The tray carrier 144 has two support sensors 185 on each side (e.g., two front sensors and two back sensors), with each sensor 185 corresponding to one of the vertical supports 181. As further described in detail below with respect to FIGS. 13-16, two elevator motors lift the tray carrier 144 and adjust, based on feedback from the sensors 185 that are responsive to vertically-spaced features (e.g., visual markers or slots) of the supports 181, the tilt or inclination of the tray carrier 144. The operation of the elevator is based on either the two front sensors 185 or the two back sensors 185. For example, if the tray 108 is to be moved to a bay 132 at the front of the tray carrier 144, the elevator motors adjust the tilt of the tray carrier 144 based on feedback from the two front sensors 185 to align the front of the tray carrier 144 with the front bay 132. Similarly, if the tray 108 is to be moved to a bay 132 at the back of the tray carrier 144, the elevator motors adjust the tilt of the tray carrier 144 based on feedback from the two back sensors 185 to align the back of the tray carrier 144 with the back bay 132.

In some implementations, adjusting the tilt of the tray carrier 144 refers to moving the tray carrier from a position in which the tray carrier is misaligned with the designated bay (e.g., a slanted or sloping position) to a position in which the tray carrier is aligned with the designated bay (e.g., a straight or leveled position, or another slanted position). For example, the elevator motors tilt the tray carrier 144 along the width of the tray carrier while the tray carrier 144 remains relatively fixed from rotation along its length.

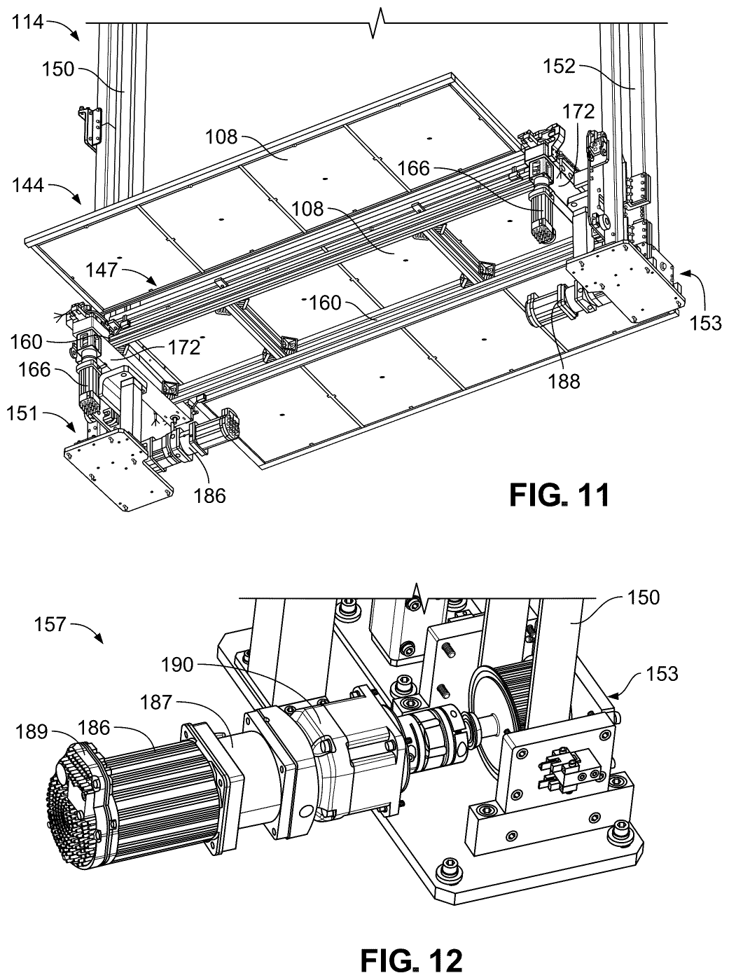

Referring back to FIG. 8, the automated elevator 144 has two vertical guide rails 154, 156, two elevator belts 150, 152, and two elevator drive assemblies 151, 153. The tray carrier 144 is attached to one side of each belt 150, 152 and is slidably engaged with each rail 154, 156 to slide up and down along the rails. The elevator drive assemblies 151, 153 are attached to the frame 130 (e.g., to the floor or wall of the frame 130). As further described in detail below with respect to FIGS. 11-12, each elevator drive assembly 151, 153 includes an elevator motor that drives each belt 150, 152 to move the tray carrier 144 up and down. Each belt 150, 152 is engaged by a pulley assembly 155 attached to the ceiling of the frame 130. Each pulley assembly 155 has a belt pulley that allows the respective belt to be driven by the elevator motors in a clockwise and counter clockwise direction to lift or lower the tray carrier 144. In some cases, the automated elevator 144 can use an elevator chain instead of a belt, and the elevator chain can be driven and engaged by different drive wheels such as sprockets.

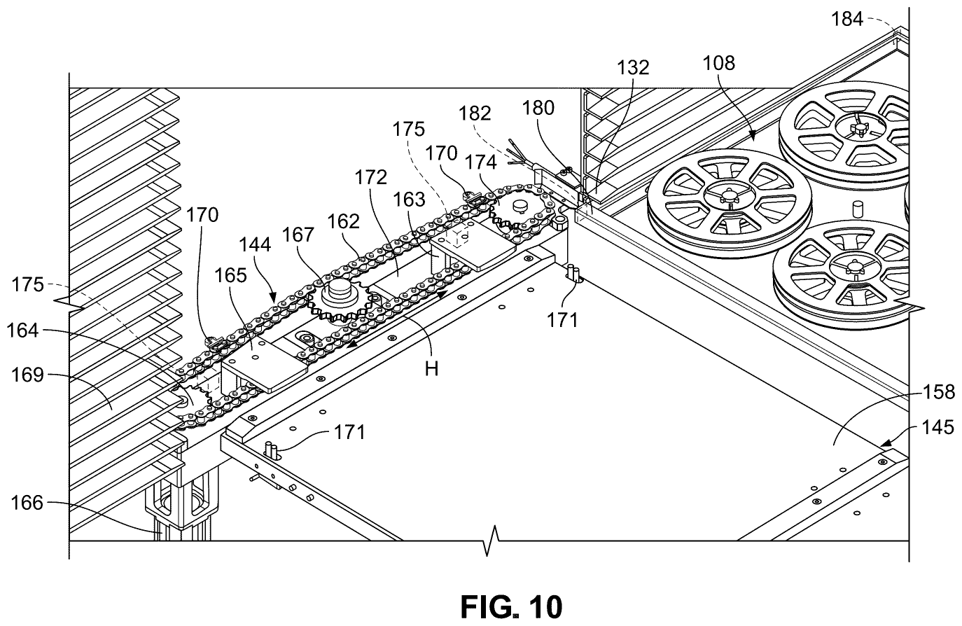

FIG. 10 shows a perspective view of part of the tray carrier 144. The tray carrier 144 has an elevator car or platform 145 with a top surface 158 that supports the tray 108 when the tray 108 is on the tray carrier 144. The platform 145 resides between two side frames 172 (only one frame 172 shown in FIG. 10). The carrier frames 172 are engaged with the elevator belts and vertical rails (shown in FIG. 9) to move the tray carrier 144 up and down. In some implementations, the platform 145 can be in the form of two or more rails or shafts that connect the two carrier frames 172 and are arranged to support the trays 108.

Each side frame 172 has a driving sprocket 164, a driven sprocket 174, and a chain 162 engaged by both sprockets. The chain 162 is driven by the driving sprocket 164. The driving sprocket 164 is driven by a tray carrier motor 166 disposed underneath the side frame 172. The sprockets 164, 174 engage the chain 162 to rotate the chain in a clockwise or counter-clockwise direction to load or offload the tray 108. For example, each chain 162 has two small hook tabs 170 (e.g., roller hooks) spaced from each other a distance corresponding to a distance between two apertures 182, 184 of the tray. The roller hooks 170 engage the tray 108 by the apertures 182, 184 to move the tray 108 in a horizontal direction “H” along a width of the carrier 144 to load or unload the tray 108 to and from the tray carrier 144. In some cases, the tray carrier 144 can have a belt instead of a chain, and the belt can be driven by respective gears, pulleys, or similar drive wheels. Additionally, instead of roller hooks 170, the tray carrier 144 can use different types of engagement members such as pins or cup hooks.

Additionally, the side frame 172 can have a tension sprocket 167 (e.g., an idler) that can be moved to increase tension in the chain 162, limiting chain slack. The driving sprocket 164 is axially attached to and rotated clockwise or counter-clockwise by the motor 166. In some implementations, the driving sprocket 164 can be at the center, with two driven sprockets at each end of the chain 162. Moreover, the side frame 172 can have one or more dampers 163 that contact the chain 162 to prevent or limit chain vibration. Each chain damper 163 can have a chain guard or cover 165 that protects the chain.

Each side frame 172 also has two hook sensors 175 (e.g., homing sensors, proximity sensors, motion detectors, or image sensors) that detect the presence and/or motion of the roller hooks 170. The sensors 175 detect the presence of the roller hooks 170 when the roller hooks 170 are in the “back” of the frame 172, as shown in FIG. 10. Because the roller hooks 170 move to the “front” to engage a tray 108, no tray 108 is on the tray carrier 144 when both roller hooks 170 are in the back. The two sensors 175 can be spaced the same distance that separates the two roller hooks 170 so that the system knows, when each sensor detects a roller hook 170, that both roller hooks 170 are in the back (and therefore no tray 108 is on the tray carrier 144).

The two carrier motors 166 are each independently operable, as a function of feedback from the sensors 175, to align the roller hooks 170 with one another. For example, the two sensors 175 of the first side frame 172 are aligned (e.g., symmetrically arranged) with the two sensors of the second side frame 172 so that the system know that, when all four sensors 175 detect the roller hooks 170 at the same time and at the same relative location, the four tabs 170 are aligned with each other. Such alignment allows the tabs 170 to engage the tray 108 at the same time to move the tray 108 from a tray slot or bay 132 to the tray carrier 144.

The tray carrier 144 can also have two tray sensors 171 (e.g., homing sensors, proximity sensors, motion detectors, or image sensors) attached to the platform 158. The sensors 171 face up to detect a presence of the tray 108. The two sensors 171 are spaced a distance slightly greater than a width of the tray such that, when the tray 108 is on the platform 158 and the sensors 171 do not detect the tray 108, the tray is at the center (or another predetermined location) of the platform 158 in between the two sensors 171. The motors 166 move the tray 108 to the center or a predetermined location of the platform 158 based on feedback from the sensors 171. In some cases, the sensors 171 can sense a visual marker or a slot at the bottom of the tray 108 to detect the position of the tray 108. The hook sensors 175 and the tray sensors 171 are connected to the processor 122 (see FIG. 1) and the motors 166 are connected to the controller 123 so that the controller controls the motors 166 based on the feedback from the sensors received by the processor to selectively move the tray 108.

FIG. 11 illustrates a bottom, perspective view of part of the automated elevator 114. The tray carrier 144 is shown with a support frame or platform 147 made of two shafts 160 that connect the two side frames 172 and are arranged to support the trays 108. The shafts 160 can have engagement features (e.g., grooves) that receive or engage engagement features (e.g. ridges) of the trays to retain the trays 108 on the tray carrier 144 while the carrier 144 moves up and down.

The elevator drive assemblies 151, 153 reside on opposite sides of the tray carrier 144. Each elevator drive assembly 151, 153 resides near a respective one of the two vertical supports 181 (shown in FIG. 9). Referring also to FIG. 12, each elevator drive assembly 151, 153 includes a drive system 157 that includes an electric motor 186, 188. Each drive assembly also includes a motor drive or controller 189 coupled to each motor, an encoder 187 attached to each motor, and a gearbox 190.

The motor drive or controller 189 can be connected to or be part of the controller 123 (shown in FIG. 1) of the rack assembly. The controller 189 controls the rotation direction and speed of the elevator motor 186. For example, the processor 122 determines the location (e.g., the height) of the designated bay, and the controller 189 moves the motors 186, 188 to drive the belts 150, 152. The belts 150, 152 are driven a predetermined distance to position the tray carrier 144 in front of or near the designated bay. The controller 189 receives information (e.g., sensor feedback such as electrical signals) from the support sensors 185 and controls, based on the sensor feedback, the two elevator motors 186, 188 to adjust the tilt of the tray carrier 144 to level the lifted tray 108 with respect to the designated bay 132.

The encoder 187 can be a rotary encoder that provides feedback signals (e.g., closed loop feedback) to the controller 189 by tracking the speed (e.g., RPM) and/or position of the shaft of the motor 186. The controller 189 uses the feedback from the encoder 187, allowing the motors 186 to move the tray carrier 144 with high precision and accuracy. For example, the controller 189 can use the encoder feedback to determine where the tray carrier 144 is located and to determine how many revolutions and degrees of a revolution (e.g., a number of encoder counts) the motor 186 needs to turn to position the tray carrier 144 at the predetermined location.

FIGS. 13-16 shows sequential steps of moving the tray carrier 144 based on feedback from sensors 185 to store a tray 108. The elevator motors move, based on feedback from the support sensors 185, the tray carrier 144 to store and retrieve trays. For example, as further described in detail below, to store a tray 108, the elevator motors first align and level, based on feedback from the support sensors 185, the tray carrier 144 with respect to the operator access station (e.g., by placing the tray carrier 144 along the same plane as the support surface 106 of the operator access station 104 shown in FIG. 1) to then move the tray 108 from the operator access station to the tray carrier 144.

Once the tray 108 is on the tray carrier 144, the elevator motors raise, based on feedback from the support sensors 185, the tray carrier to the designated bay to store the tray 108. Each support sensor 185 is responsive to vertically-spaced features 192 of a respective one of the vertical supports 181. The vertically-spaced features 192 can be visual markers (e.g., black dots or lines), holes, slots, or similar features spaced apart and distributed along the length of the vertical supports 181. The slots 192 are arranged in pairs, with one slot of each pair located on the right side of a respective bay 132 (as shown in FIG. 13) and the other slot 192 of the pair residing on the left side (not shown) of the bay 132. Each pair of slots is associated with a bay 132 and resides below, above, or anywhere along the height of such bay 132. Each slot of the pair of slots can be at the same elevation as each other or at different elevations.

The slots are used as visual reference for leveling the tray carrier 144 with respect to the bay 132 once the tray carrier 144 is near the bay 132. For example, the elevator motors first raise the tray carrier 144 to an initial position (e.g., right below or above the slots 132 of the selected bay 132). The elevator motors can raise the tray carrier 144 to the initial position by rotating the shaft of the elevator motors a predetermined number of revolutions (e.g., a large number of encoder counts). The initial position can be a predetermined distance from the floor or another point of reference (and measured as encoder counts), and can be determined without or without feedback from the sensors 185.

Then, the elevator motors continue to move the tray carrier 144 up or down 132 to a second position, where the sensors 185 initially sense a starting point of the slots 132 (or one of the slots) of the selected bay 132. The elevator motors can raise the tray carrier 144 to the second position by rotating the shaft of the elevator motors a predetermined number of degrees of a revolution (e.g., a small number of encoder counts).

Then, the elevator motors move, as a function of feedback from the support sensors 185, the tray carrier 144 up or down to a final position. For example, the motors move the tray carrier 144 using the starting point of each slot 132 as a reference, thereby tilting the tray carrier 144 (if needed) to level the tray carrier 144 with the bay 132. For example, once the left sensor 185 detects the left slot 192, the shaft of the left motor rotates a predetermined number of degrees of a revolution (e.g., a small number of encoder counts) to raise or lower the left side of the tray carrier 144 to a predetermined elevation. Similarly, when the right sensor 185 detects the right slot 192, the shaft of the right motor rotates a predetermined number of degrees of a revolution (e.g., a small number of encoder counts) to raise or lower the right side of the tray carrier 144 to a predetermined elevation, thus leveling or aligning the tray carrier 144 with the bay 132. The support sensors 185 can detect their respective slots 192 at the same time or at different times, and each slot can be associated with a different number of encoder counts needed from the starting point of the slot to level the tray carrier 144. In some cases, the final position of the tray carrier 144 can be the position in which both sensors initially detect the starting point of the slots 132. In other words, the second position can be the same as the final position if the slots are in the exact location in which, when the sensors 185 initially detect the slots 192, the tray carrier 144 is aligned and leveled with the bay 132.

Leveling and aligning the tray carrier 144 with the bay 132 can include placing the chains 162 of the tray carrier 144 along a central horizontal plane of the bay 132. In some cases, leveling and aligning the tray carrier 144 with the bay 132 can include placing the chains 162 of the tray carrier 144 along a central horizontal plane of the tray 108 to be engaged. With the tray carrier 144 leveled and aligned, the tray carrier 144 moves the tray 108 from the bay 132 onto the tray carrier 144 (during retrieval of the tray 108) or moves the tray 108 from the tray carrier 144 to the bay (during storage of the tray 108).

Thus, the two elevator motors are each independently operable to raise the tray carrier 144 to at least approximate alignment with the designated bay 132 and, as a function of feedback from the sensors 185, adjust a tilt of the tray carrier 144 to level the lifted tray 108 with respect to the designated bay 132. For example, the motors can first raise, based on feedback from a motor encoder, the tray carrier 144 to a first predetermined location near the bay 132. Then, the elevator motors level the tray carrier 144 based on sensor feedback by lifting or lowering each side of the carrier 144 a distance from the slots. In some cases, the motors can use the feedback from the sensors 185 to both raise the tray carrier 144 and level the tray carrier 144. Thus, the automated elevator 114 can automatically compensate for imperfect mechanical assembly and alignment.

FIG. 13 shows the tray carrier 144 raised to a first position near the designated bay 132. In the first position, the tray carrier 144 is at least in approximate alignment with the designated bay 132. FIG. 14 shows the tray carrier 144 lifted to a second position in which the sensors 185 first sense the slot 192. Once the tray carrier 144 is at the second position, the tray 144 either is aligned with the bay 132 or is at a predetermined distance away from alignment with the bay 132. For example, if the slots 192 are not at the exact position in which the tray carrier 144 is aligned with the bay 132, the motors move the tray carrier 144 a predetermined distance to a third position (e.g., slightly past the slots) to align the tray carrier 144 with the bay 132.

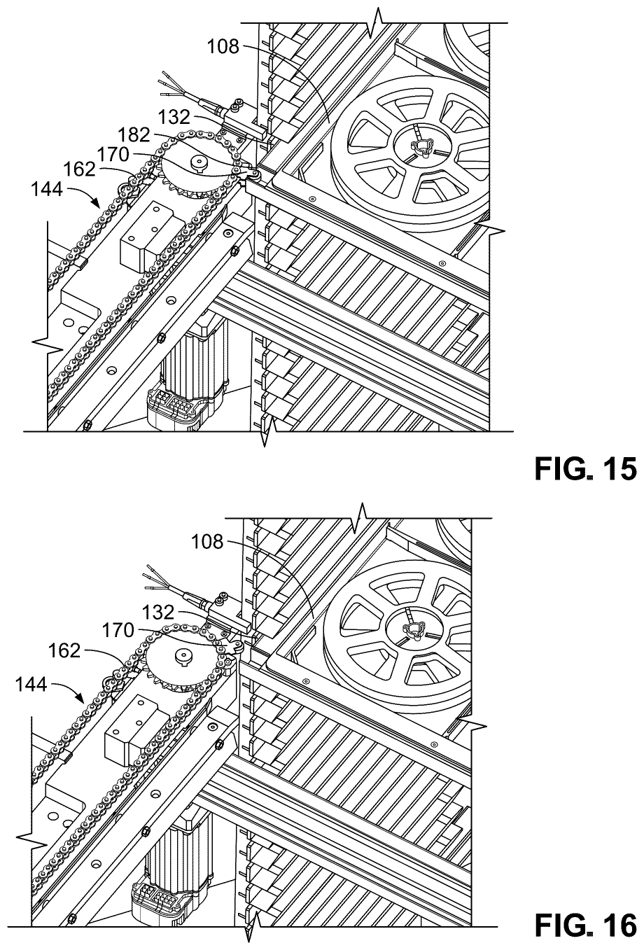

As shown in FIGS. 15 and 16, to store the tray 108, once the tray carrier 144 is leveled and aligned with the bay 132, the tray carrier motor drives the two chains 162 of the tray carrier 144 to move the tray 108 from the tray carrier 144 into the designated bay 132. Specifically, the chain 162 is driven, from top view, in a counterclockwise direction to move, with the roller hooks 170 engaging the tray 108, the tray 108 into the designated bay 132. The roller hooks 170 are inside the apertures 182 of the tray 108 while the tray is on the tray carrier 144. As shown in FIG. 16, to move the tray 108 into its designated bay 132, the roller hooks 170 push the tray 108 into the bay 132 until each hook 170 turns about the driven sprocket of the tray carrier 144. Once the last roller hook 170 disengages the tray 108, the tray 108 is in its stored position within the storage stack.

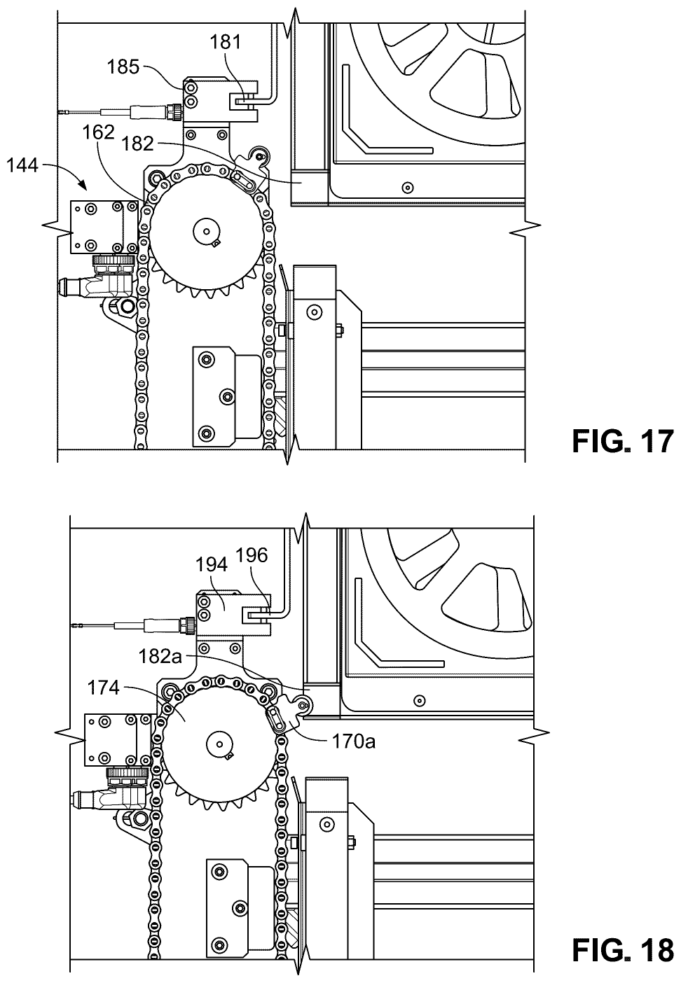

FIGS. 17-20 show sequential steps of retrieving a tray 10 from its storage bay 132 (or from the operator access station). As shown in FIG. 17, to load the tray 108 onto the tray carrier 144, the tray carrier 144 is first aligned and leveled with the bay 132. The tray carrier 144 is leveled with the bay 132 using sensor feedback and the same process as described above with respect to FIGS. 13-16. When the tray carrier 144 is leveled with the bay 132, the chain 162 of the tray carrier 144 is disposed along a horizontal plane across the apertures 182 of the tray 108.

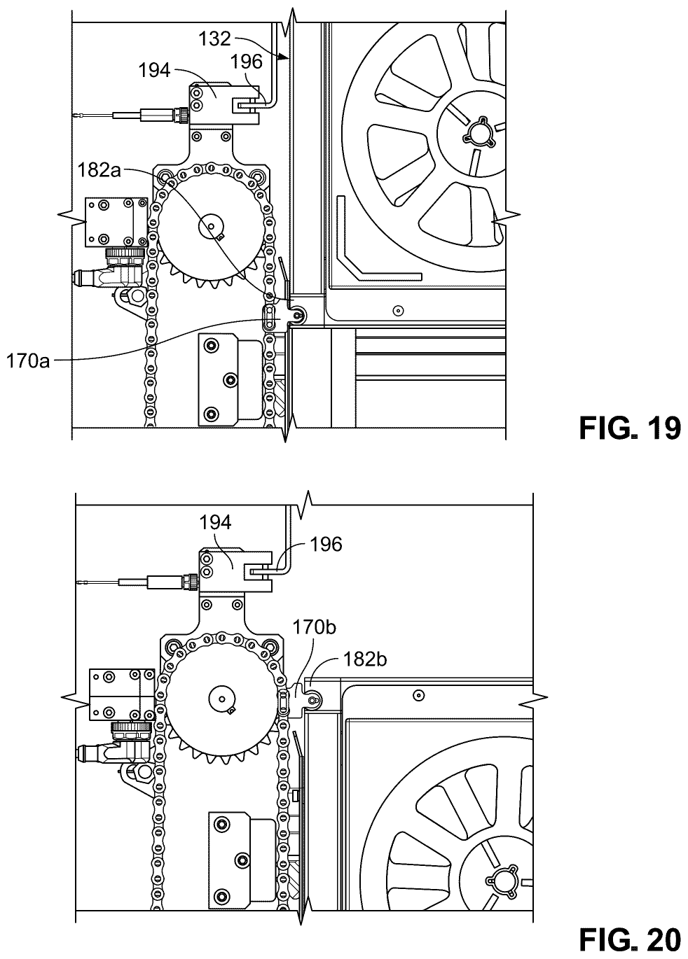

As shown in FIGS. 18 and 19, the front sprocket 174 near the first aperture 182a of the tray 108 is sized and spaced from the first aperture 182a a distance such that the first roller hook 170a enters the first aperture 182a as the roller hook 170a rotates along the front sprocket 174. Similarly, as shown in FIG. 20, the front sprocket 174 and second roller hook 170b are arranged such that the second roller hook 170b enters the last aperture 182b of the tray 108 as the tray 108 is loaded onto the tray carrier 144. Thus, when the tray 108 is on the tray carrier 144, both tabs 170a, 170b are disposed inside the apertures 182a, 182b of the tray 108.

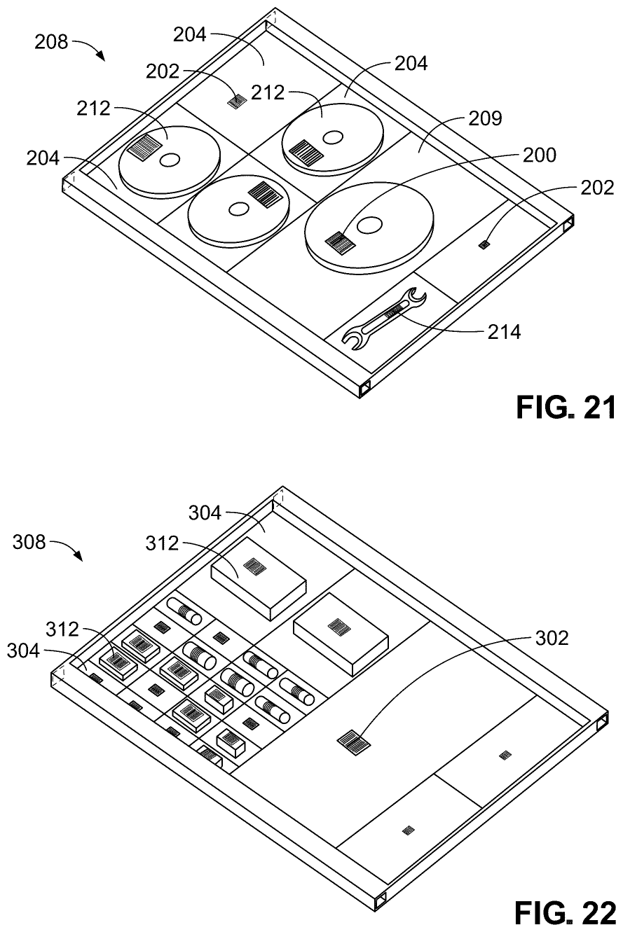

FIG. 21 shows a perspective view of a tray 208 according to a first implementation of the present disclosure. The tray 208 contains multiple component reels 212. The tray 208 includes multiple discrete tray storage locations or spaces 204. Each space 204 can be arranged to contain one component or item such as a component reel 212 or tool 214 (e.g., a hand tool). The system can determine the location of each storage location 204 by the position of storage location 204 in the image captured by the camera of the operator access station. For example, each tray 208 can have an associated grid (e.g., a four, six, or eight square grid) and the system determines what type of grid corresponds with the tray 208 and then divides the image with the corresponding grid to determine which component 212 is in which location or space 204 of the tray. In some cases, the tray 208 can include visual lines 209 or shapes that make up the grid or that otherwise delineate the boundaries of each storage location 204 so that the image shows the locations or spaces 204. Having marked trays 208 with delineated boundaries can simplify the process or reduce the steps needed to determine the location of each component 212.

In some implementations, each space or location 204 can have an identifier 202 on the tray 208. The identifier 202 can be used to determine the location of each space 204, and also to determine if there is a component on the space 204 (and if the component 212 has been placed upright or upside down). The space identifier 202 is exposed when no component 212 is in the respective component storage location 204, and covered when a component 212 is in the component storage location 204. The identifier 202 can be a simple binary mark (e.g., a black dot) or machine-readable code (e.g., a bar code) containing information, such as the identity and location of the empty space 204.

Additionally, each item 212 can have a machine-readable code 200 on one side of the component. The processor uses the code 200 to identify the component and associate the component 212 to its respective space 204. For example, when storing component reels, the code 200 can include information about what type of electronic components the reel has. Additionally, each component 212 can have two or more machine-readable codes. For example, one code can be associated with the contents of the item, and the other code can be associated with the container of the item for inventory purposes.

FIG. 22 illustrates a tray 308 according to a second implementation of the present disclosure. The tray 308 is similar to the tray 208 in FIG. 21, with the main exception that some or all storage locations 304 are arranged to contain smaller items such as prescription medications 312 or other pharmaceutical products. The tray 308 has multiple discrete tray storage locations 204, some of different sizes. Each location 204 can be defined by a grid similar to the grid of the tray 208 in FIG. 21. The storage spaces 304 also have a visual identifier 302 and the items 312 also have identifiers such as machine-readable codes.

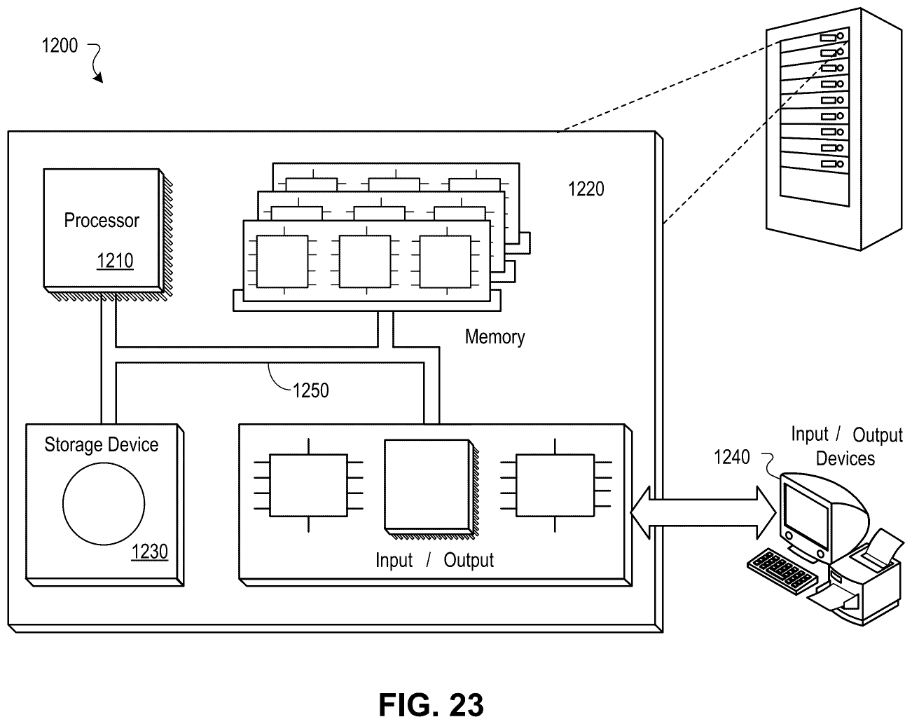

FIG. 23 is a schematic illustration of an example control system or controller for a vertical component storage system according to the present disclosure. For example, the controller 1200 may include or be part of the controllers 123, 189 shown in FIGS. 1 and 12. The controller 1200 is intended to include various forms of digital computers, such as printed circuit boards (PCB), processors, digital circuitry, or otherwise. Additionally, the system can include portable storage media, such as, Universal Serial Bus (USB) flash drives. For example, the USB flash drives may store operating systems and other applications. The USB flash drives can include input/output components, such as a wireless transmitter or USB connector that may be inserted into a USB port of another computing device.

The controller 1200 includes a processor 1210, a memory 1220, a storage device 1230, and an input/output device 1240. Each of the components 1210, 1220, 1230, and 1240 are interconnected using a system bus 1250. The processor 1210 is capable of processing instructions for execution within the controller 1200. The processor may be designed using any of a number of architectures. For example, the processor 1210 may be a CISC (Complex Instruction Set Computers) processor, a RISC (Reduced Instruction Set Computer) processor, or a MISC (Minimal Instruction Set Computer) processor.

In one implementation, the processor 1210 is a single-threaded processor. In another implementation, the processor 1210 is a multi-threaded processor. The processor 1210 is capable of processing instructions stored in the memory 1220 or on the storage device 1230 to display graphical information for a user interface on the input/output device 1240.

The memory 1220 stores information within the controller 1200. In one implementation, the memory 1220 is a computer-readable medium. In one implementation, the memory 1220 is a volatile memory unit. In another implementation, the memory 1220 is a non-volatile memory unit.

The storage device 1230 is capable of providing mass storage for the controller 1200. In one implementation, the storage device 1230 is a computer-readable medium. In various different implementations, the storage device 1230 may be a floppy disk device, a hard disk device, an optical disk device, or a tape device. In various different implementations, the storage device 1230 may be a data base that allows the system to manage multiple storage stacks.

The input/output device 1240 provides input/output operations for the controller 1200. In one implementation, the input/output device 1240 includes a keyboard and/or pointing device. In another implementation, the input/output device 1240 includes a display unit for displaying graphical user interfaces.

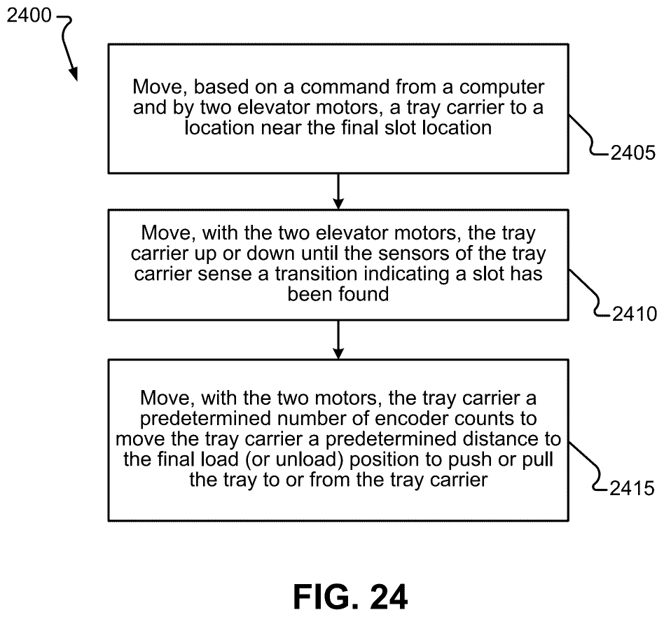

FIG. 24 shows a flow chart of a method (2400) of moving the tray carrier to store or retrieve a tray. The method includes first moving, based on a command (e.g., a command including a slot number or location) from a computer and by two elevator motors, a tray carrier to a location near the final slot location (2405). The method also includes moving, with the two elevator motors, the tray carrier up or down until the sensors of the tray carrier sense a transition indicating a slot has been found (2310). The method also includes moving, with the two motors, the tray carrier a predetermined number of encoder counts to move the tray carrier a predetermined distance to the final load (or unload) position to push or pull the tray to or from the tray carrier (2415).

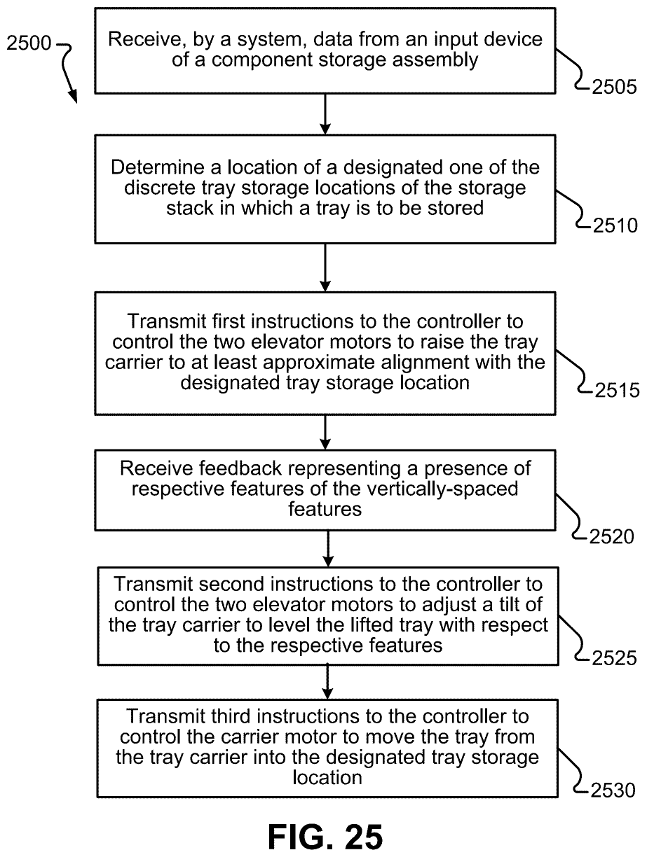

FIG. 25 shows a flow chart of a method (2500) of storing a tray. The method includes receiving, by a system including one or more computers in one or more locations, data from an input device of a component storage assembly, the component storage assembly including a storage stack with an operator access station and defining discrete tray storage locations residing between vertical stack supports and an elevator configured to store trays from the operator access station in the storage stack elevator. The elevator includes a tray carrier with a carrier motor, two elevator motors operable to lift the tray carrier, a controller configured to control the two elevator motors, and support sensors attached to the tray carrier. Each support sensor is positioned to be responsive to vertically-spaced features of a respective one of the vertical stack supports (2505). The method also includes determining, by the system and based on the data from the input device, a location of a designated one of the discrete tray storage locations of the storage stack in which a tray is to be stored (2510). The method also includes transmitting, by the system and based on the determined location, first instructions to the controller to control the two elevator motors to raise the tray carrier to at least approximate alignment with the designated tray storage location. The tray carrier supports the tray (2515). The method also includes receiving, by the system and from the support sensors, feedback representing a presence of respective features of the vertically-spaced features (2520). The method also includes transmitting, by the system and based on the sensor feedback, second instructions to the controller to control the two elevator motors to adjust a tilt of the tray carrier to level the lifted tray with respect to the respective features (2525). The method also includes transmitting, by the system, third instructions to the controller to control the carrier motor to move the tray from the tray carrier into the designated tray storage location (2530).

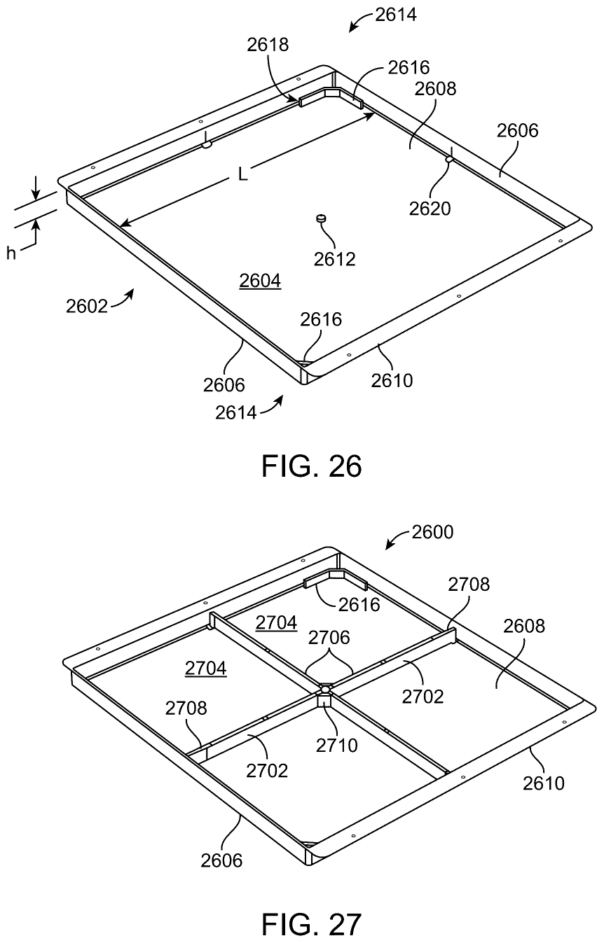

Referring next to FIGS. 26 and 27, a tray 2600 usable in the storage system described above has a tray body 2602 with a bottom surface 2604 and four side walls 2606 defining a shallow recess 2608 therebetween. Two opposite side walls feature outwardly-extending lips 2610. The tray is shallow, with side walls 2608 preferably extending to a height ‘h’ less than about ten percent of a maximum overall length ‘L’ of any of the side walls. The recess in this example is about 15 inches square and the side walls are about 0.84 inch high. The tray can accommodate, for example, four smaller reels of electrical components or one large reel. The tray body 2602, shown in FIG. 26 without any dividers, can be molded of ABS resin.

As shown in FIG. 27, tray dividers 2702 can be attached to the tray body to divide recess 2608 into smaller areas, such as to form compartments 2704 for storing separate, smaller component reels or other items. Each tray divider 2702 is L-shaped, with two arms 2706 extending to respective arm ends 2708 that releasably latch to the tray body. There are two tray dividers 2702 shown in FIG. 27, each with two arms 2706 extending from a hub 2710 of the tray divider. Deployed as shown in FIG. 27, the hubs 2710 of the tray dividers are disposed adjacent one another at or near the center of the tray. In this deployed position, the arm ends 2708 are secured to two adjacent side walls 2606 of the tray body with the two arms 2706 otherwise spaced from the side walls to define a tray receptacle of an area smaller than the recess. The bottom surface of the tray body can be provided with a hole 2612 (FIG. 26) or other feature to engage with a removable fastener (not shown) to secure the hub of one or both of the tray dividers to the tray body when deployed. The tray divider hubs 2710 can define semi-cylindrical surfaces that face one another to form a fastener passage. The hole 2612 in the bottom surface of the tray can be provided with side notches that receive tabs of the hubs to help locate the hubs to the hole.

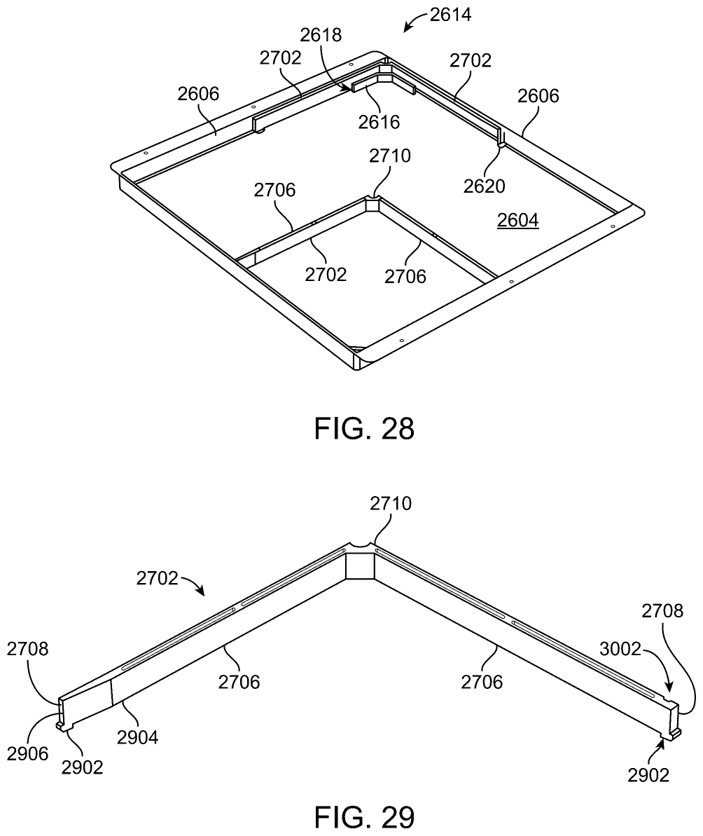

Referring next to FIG. 28, the tray dividers 2702 can be moved to stowed positions when not in use, thereby opening up the recess 2608 to accommodate a larger item. FIG. 28 illustrates one tray divider deployed as shown in FIG. 27, and another tray divider 2702 in a stowed position in an opposite corner 2614 of the recess with its two arms 2706 lying along two adjacent side walls 2606 that meet at the corner. If desired, both tray dividers 2702 can be stowed in opposite corners. To help hold tray dividers in such stowed positions, the tray body has a corner wall 2616 extending from the bottom surface 2604 into the recess adjacent the two adjacent side walls to define a space 2618 sized to accommodate the tray divider in its stowed position.

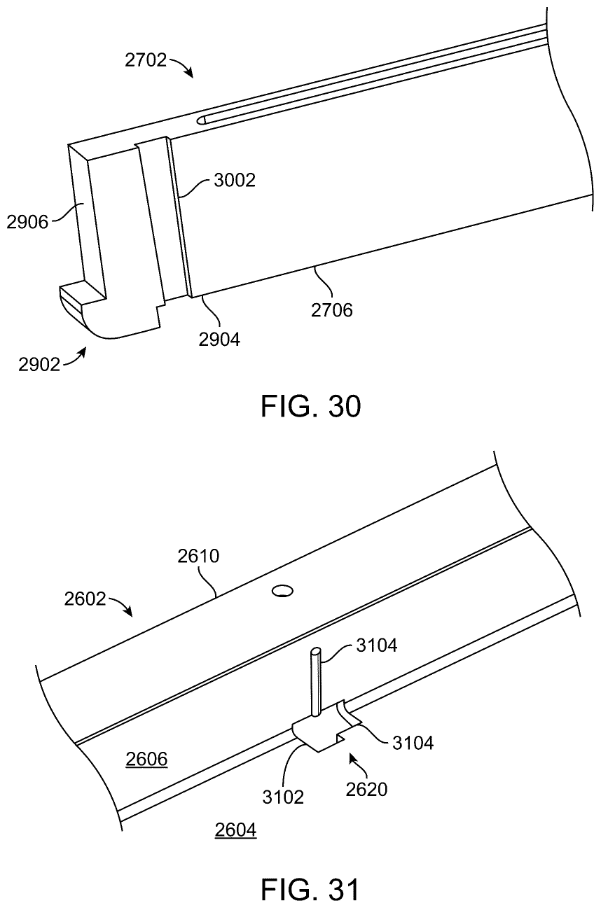

Referring to FIGS. 29 and 30, tray divider 2702 is formed of molded resin and each arm 2706 extends from hub 2710 to a respective arm end 2708 with a projection 2902 that extends both beyond an underside 2904 of the arm and beyond a nominal distal end 2906 of the arm, to form a pawl.

Referring next to FIG. 31, the tray body 2602 features, at or near a midpoint of each side wall 2606 at an intersection of the side wall with the bottom surface 2604 of the tray body, a latching notch 2620. The bottom surface defines four such notches 2620, each adjacent one of the side walls and configured to mate with the pawls of the arm ends of the tray dividers to releasably secure the arm ends to the tray body with the tray dividers in their deployed positions.

Each notch 2620 has a release portion 3102 contiguous with a latch portion 3104. The release portion 3102 is sized to accept the projection 2902 (FIG. 30) of the arm end as the tray divider is placed against the bottom surface. The latch portion 3104 is sized to prevent release of the projection with the projection moved along the side wall from the release portion into the latch portion. To this end, the release portion 3102 extends a greater distance from the side wall than does the latch portion. The release portion is of sufficient length from the side wall that the projection can be moved vertically down into the notch at the release portion. Once in the notch, the arm end can be moved laterally along the side wall until the projection is disposed in the latch portion of the notch. Once in that position, the arm end is secured to the tray body until the projection is moved back into the release portion of the notch.

To resist motion of the arm end between the release and latch portions of the notch, the side wall is provided with a detent 3104, in this case a rib extending into the recess, that provides a slight interference fit with the nominal distal end 2906 (FIG. 30) of the arm of the tray divider. As the projection is moved from the release portion to the latch portion of the notch, the arm end snaps past the rib. As can be seen best in FIG. 30, one arm of the tray divider defines a groove 3002 positioned to accommodate the rib when the tray divider is in its stowed position.

While a number of examples have been described for illustration purposes, the foregoing description is not intended to limit the scope of the invention, which is defined by the scope of the appended claims. There are and will be other examples and modifications within the scope of the following claims.

What is claimed is:

1. A component storage system, comprising:
a storage stack defining discrete tray storage locations spaced vertically along the stack between vertical stack supports;
an operator access station comprising a surface adapted to support a movable tray; and
an automated elevator configured to store trays in the storage stack by lifting a tray from the access station surface to an elevation of a designated one of the discrete tray storage locations of the storage stack, and then moving the lifted tray into the designated tray storage location between the vertical stack supports, the automated elevator comprising:
a tray carrier comprising a carrier motor operable to move the tray from the tray carrier into the designated tray storage location once the tray carrier is vertically aligned with the designated tray storage location,
two elevator motors operable to lift the tray carrier, the elevator motors spaced apart such that each elevator motor is closer to a respective one of the vertical stack supports, and
two support sensors attached to the tray carrier, each support sensor positioned to be responsive to vertically-spaced features of a respective one of the vertical stack supports;
wherein the two elevator motors are each independently operable to raise the tray carrier to at least approximate alignment with the designated tray storage location and, as a function of feedback from the support sensors, to adjust a tilt of the tray carrier to level the lifted tray with respect to the storage stack.

2. The component storage system of claim 1, further comprising a controller configured to receive information from the two support sensors, the controller configured to control, based on the information received from the two support sensors, the two elevator motors to adjust the tilt of the tray carrier to level the lifted tray with respect to the vertically-spaced features, aligning the tray carrier with the designated tray storage location.

3. The component storage system of claim 2, wherein the controller is configured to control the two elevator motors to first raise the tray carrier to a first elevation before the support sensors detect the vertically-spaced features, then to a second elevation in which the support sensors initially detect a point of the vertically-spaced features, and then to a third elevation in which the support sensors are spaced a predetermined vertical distance from the vertically spaced features and the tray carrier is aligned with the designated tray storage location.

4. The component storage system of claim 1, wherein the automated elevator is configured to retrieve a selected tray from the storage stack by extracting the selected tray from its respective tray storage location and moving the selected tray to the operator access station, wherein extracting the selected tray comprises moving the tray carrier to at least approximate alignment with the tray storage location, adjusting, as a function of feedback from the support sensors, the tilt of the tray carrier to level the tray carrier with respect to the respective tray storage location, and then pulling the selected tray unto a support surface of the tray carrier.

5. The component storage system of claim 1, wherein the automated elevator further comprises two belts each engaged with and configured to be driven by a respective one of the two elevator motors, each of the two belts attached to a respective end of the tray carrier to selectively raise each of the ends independently from each other to adjust the tilt of the tray carrier to level the lifted tray with respect to the storage stack.

6. The component storage system of claim 1, wherein the vertically-spaced features comprise a plurality of pairs of visual features, each pair associated with one of the discrete tray storage locations and detectable by the two support sensors, and the two elevator motors are configured to raise the tray carrier to a predetermined elevation along the storage stack, and then move, as a function of feedback from the support sensors detecting the pair of visual features, the tray carrier to a final position with respect to the respective pair of visual features.

7. The component storage system of claim 6, wherein each of the two elevator motors is coupled to an encoder, the elevator motors operable to raise the tray carrier based on feedback from the encoder both to raise the tray carrier to at least approximate alignment with the designated tray storage location, and to adjust the tilt of the tray carrier.

8. The component storage system of claim 6, wherein the vertical stack supports comprise two columns of a frame of a vertical storage rack, each of the two columns defining holes and each pair of visual features comprising a pair of holes, each hole of the pair of holes residing on one side of a respective discrete tray storage location and residing at the same elevation.

9. The component storage system of claim 1, wherein the tray carrier further comprises:
a second carrier motor, the two carrier motors operable to move a plurality of tabs that engage a respective side of the tray to load the tray on the tray carrier or offload the tray from the tray carrier, and
two tab sensors attached to the tray carrier, each tab sensor positioned to be responsive to the presence of a respective one of the tabs, the component storage system configured to determine, based on feedback from the tab sensors, whether a tray is on or off the tray carrier.

10. The component storage system of claim 9, wherein the tray carrier further comprises two chains each configured to be driven by one of the carrier motors, the plurality of tabs comprising two tabs attached to one of the two chains to engage one side of the tray and two tabs attached to the other one of the two chains to engage an opposite side of the tray, and the carrier motors are each independently operable, as a function of feedback from the tab sensors, to align the tabs of one of the two chains with the tabs of the other one of the two chains to allow the tabs to engage and move the tray from a tray storage location to the tray carrier in between the two chains.

11. The component storage system of claim 1, wherein the access station comprises a camera positioned such that a tray supported on the surface is within a field of view of the camera, the field of view spanning multiple discrete component storage locations of the tray, the camera configured to generate data representing an image of the tray, from which the system is configured to (a) identify a component on the tray, and (b) determine where on the tray the component is located, and wherein the component storage system comprises a machine learning image processing system configured to process the data from the camera and identify, based on a machine learning algorithm, each component on the tray based on a physical characteristic of the component.

12. A storage system, comprising:
a storage stack defining discrete tray storage locations residing between vertical stack supports; and
an elevator configured to store trays in the storage stack by moving a tray from an access station of the storage stack to an elevation of a designated one of the discrete tray storage locations of the storage stack, and then moving the lifted tray into the designated tray storage location, the elevator comprising:
a tray carrier comprising a carrier motor operable to move the tray from the tray carrier into the designated tray storage location, and
two elevator motors operable to lift the tray carrier, the elevator motors spaced apart such that each elevator motor moves a side of the tray carrier that is closer to a respective one of the vertical stack supports, the two elevator motors each being independently operable to first raise the tray carrier to a first elevation, and then, as a function of feedback from support sensors positioned to be responsive to vertically-spaced features of a respective one of the vertical stack supports, to a second elevation in which the tray carrier is leveled with respect to the designated tray storage location.

13. The storage system of claim 12, further comprising a controller configured to receive information from the two support sensors, the controller configured to control, based on the information received from the two support sensors, the two elevator motors to adjust a tilt of the tray carrier to level the lifted tray with respect to the vertically-spaced features, aligning the tray carrier with the designated tray storage location.

14. The storage system of claim 13, wherein the controller is configured to control the two elevator motors to first raise the tray carrier to a first elevation in which the support sensors initially detect a point of the vertically-spaced features, and then to a second elevation in which the support sensors are spaced a predetermined vertical distance from the vertically spaced features and the tray carrier is aligned with the designated tray storage location.

15. The storage system of claim 12, wherein the access station comprises a camera positioned such that a tray supported on a surface of the access station is within a field of view of the camera, the field of view spanning multiple discrete component storage locations of the tray, the camera configured to generate data representing an image of the tray, from which the system is configured to (a) identify a component on the tray, and (b) determine where on the tray the component is located, and wherein the storage system comprises a machine learning image processing system configured to process the data from the camera and identify, based on a machine learning algorithm, each component on the tray based on a physical characteristic of the component.

16. A system, comprising:
at least one processing device; and
a memory communicatively coupled to the at least one processing device, the memory storing instructions which, when executed, cause the at least one processing device to perform operations comprising:
receive data from an input device of a component storage assembly, the component storage assembly comprising a storage stack defining discrete tray storage locations residing between vertical stack supports and an elevator configured to store trays in the storage stack, the elevator comprising a tray carrier with a carrier motor, two elevator motors operable to lift the tray carrier, a controller configured to control the two elevator motors, and support sensors attached to the tray carrier, each support sensor positioned to be responsive to vertically-spaced features of a respective one of the vertical stack supports;
determine, based on the data from the input device, a location of a designated one of the discrete tray storage locations of the storage stack in which a tray is to be stored;
transmit, based on the determined location, first instructions to the controller to control the two elevator motors to raise the tray carrier to at least approximate alignment with the designated tray storage location;
receive, from the support sensors, feedback representing a presence of at least one of the vertically-spaced features;
transmit, based on the sensor feedback, second instructions to the controller to control the two elevator motors to adjust a tilt of the tray carrier to level the lifted tray with respect to the respective features; and
transmit third instructions to the controller to control the carrier motor to move the tray from the tray carrier into the designated tray storage location.

17. A method, comprising:
receiving, by a system comprising one or more computers in one or more locations, data from an input device of a component storage assembly, the component storage assembly comprising a storage stack comprising an operator access station and defining discrete tray storage locations residing between vertical stack supports and an elevator configured to store trays from the operator access station in the storage stack, the elevator comprising a tray carrier with a carrier motor, two elevator motors operable to lift the tray carrier, a controller configured to control the two elevator motors, and support sensors attached to the tray carrier, each support sensor positioned to be responsive to vertically-spaced features of a respective one of the vertical stack supports;
determining, by the system and based on the data from the input device, a location of a designated one of the discrete tray storage locations of the storage stack in which a tray is to be stored;
transmitting, by the system and based on the determined location, first instructions to the controller to control the two elevator motors to raise the tray carrier to at least approximate alignment with the designated tray storage location, the tray carrier supporting the tray;
receiving, by the system and from the support sensors, feedback representing a presence of respective features of the vertically-spaced features;
transmitting, by the system and based on the sensor feedback, second instructions to the controller to control the two elevator motors to adjust a tilt of the tray carrier to level the lifted tray with respect to the respective features; and
transmitting, by the system, third instructions to the controller to control the carrier motor to move the tray from the tray carrier into the designated tray storage location.

18. A configurable component storage tray, comprising:
a tray body having a bottom surface and four side walls defining a recess therebetween;
an L-shaped tray divider having two arms extending to respective arm ends, the divider selectively positionable in two different positions within the recess, including
a deployed position in which the arm ends are secured to two adjacent side walls of the tray body with the two arms otherwise spaced from the side walls to define a tray receptacle of an area smaller than the recess; and
a stowed position in which the two arms lie along the two adjacent side walls, such that the divider is stowed in a corner of the tray body.

19. The configurable component storage tray of claim 18, wherein the tray body further comprises a corner wall extending from the bottom surface into the recess adjacent the two adjacent side walls to define a space sized to accommodate the tray divider in its stowed position, with the tray divider positioned between the corner wall and the two adjacent side walls.

20. The configurable component storage tray of claim 18, wherein the L-shaped tray divider is a first tray divider, the tray receptacle is a first tray receptacle and the corner is a first corner, the storage tray further comprising a second tray divider having two arms extending to respective arm ends, the divider selectively positionable in two different positions within the recess, including
a deployed position in which the arm ends are secured to two adjacent side walls of the tray body with the two arms otherwise spaced from the side walls to define a second tray receptacle of an area smaller than the recess; and
a stowed position in which the two arms lie along the two adjacent side walls, such that the divider is stowed in a second corner of the tray body opposite the first corner.
